(19) United States
(12) Patent Application Publication
(10) Pub. No.: US 2026/0247780 A1
(43) Pub. Date: Aug. 20, 2026

(54) OPTOELECTRONIC DEVICE AND MANUFACTURING METHOD

(71) Applicant: ALEDIA, Champagnier (FR)

(72) Inventor: Tiphaine DUPONT, Grenoble (FR)

(73) Assignee: ALEDIA, Champagnier (FR)

(21) Appl. No.: 18/878,944

(22) PCT Filed: Jun. 27, 2023
(86) PCT No.: PCT/EP2023/067533

§ 371 Date: Dec. 26, 2024

(30) Foreign Application Priority Data
Jun. 28, 2022 (FR) FR2206464

(51) Int. Cl. H10H 29/80; H10H 29/01; H10H 29/24

(52) U.S. Cl. CPC H10H 29/962; H10H 29/032; H10H 29/0362; H10H 29/24; H10H 29/8323; H10H 29/8325

(57) ABSTRACT

The object of the invention is an optoelectronic device comprising a plurality of emitting layers (1, 2, 3) in a stack in a direction z, comprising at least:
A first emitting layer (1) configured to emit radiation at a wavelength λ1,
A second emitting layer (2) configured to emit radiation at a second wavelength λ2 different from λ1,
said emitting layers (1, 2, 3) being superimposed in projection along the direction z,

Advantageously, each of the emitting layers (1, 2, 3) comprises a set (10, 20, 30) of nanowires (100, 200, 300) oriented longitudinally in the direction z forming the active part of the emitting layer (1, 2, 3).

Another object of the invention is a method for manufacturing such a device.

Figure for the abstract: FIG. 3.

### TECHNICAL FIELD OF THE INVENTION

The present invention relates to the field of technologies for microelectronics and optoelectronics. It finds a particularly advantageous application in the manufacture of optoelectronic devices, in particular pixels based on light-emitting diodes (LEDs).

### PRIOR ART

A self-emitting display screen is an example of optoelectronic device comprising a plurality of pixels emitting their own light. Each pixel can thus be formed by one or more LEDs or micro-LEDs.

A pixel is typically formed by three subpixels each emitting a radiation with a different color, conventionally in green, red and blue. RGB (the acronym for “Red Green Blue”) subpixels are generally disposed side by side, either by being directly manufactured side by side or by being extracted from various wafers and then transferred side by side. The size of the pixel here corresponds approximately to the sum of the sizes of the subpixels that constitute it. Placing or manufacturing the subpixels side by side requires precise transfer or masking steps.

To increase the resolution of the screen, it is necessary to reduce the size of the pixels. One challenge consists in reducing the size of the pixels below 50 λm, or even below 10 μm. The precision required for the transfer or masking steps is all the greater.

One solution for reducing the size of the pixel without critically increasing the manufacturing precision required is to superimpose the various subpixels constituting this pixel. In this architecture, the light emitted by the pixel at the bottom passes through the pixels located above it.

The document U.S. Pat. No. 8,269,229 B2 discloses such a solution consisting in stacking various LEDs in the emission direction of the LEDs. One drawback of this solution is that the efficacy of extraction of the light significantly decreases.

To overcome this decrease, the document U.S. Pat. No. 8,567,960 B2 discloses a solution consisting in forming vertical waveguides regularly distributed through a stack of laser diodes. This solution does not make it possible to significantly increase the efficacy of extraction of the light. Moreover, this solution requires additional steps for forming the waveguides. This architecture is complex and not very effective.

Another solution disclosed by the document “Eu-doped GaN and InGaN monolithically stacked full-color LEDs with a wide color
Gamut, Shuhei Ichikawa et al., Applied Physics Express 14, 031008 (2021)” consists in superimposing the various LEDs only in part. In this way, the emissive surfaces of the various LEDs are staged. This staircase architecture does not make it possible to significantly reduce the size of the pixel.

The present invention aims to at least partially overcome the drawbacks of the aforementioned solutions.

In particular, one object of the present invention is to propose an optoelectronic device comprising at least two sub-pixels, making it possible to increase the pixel density of a screen and having improved light-extraction efficacy. Another object of the present invention is to propose a method of manufacturing such an optoelectronic device.

The other objects, features and advantages of the present invention will be clear after an examination of the following description and the accompanying drawings. It is understood that other advantages can be incorporated. In particular, certain features and certain advantages of the device may apply mutatis mutandis to the method, and vice versa.

### SUMMARY OF THE INVENTION

To achieve the objectives mentioned above, one aspect relates to an optoelectronic device comprising a plurality of emitting layers in a stack in a direction z, said plurality of emitting layers comprising at least:
A first emitting layer comprising a first active part configured to emit a first radiation at a first wavelength λ1,
A second emitting layer comprising a second active part configured to emit a second radiation at a second wavelength λ2 different from the first wavelength λ1.

Advantageously, the emitting layers are at least partly superimposed in projection along the direction z.

Each emitting layer furthermore comprises, on either side of the active part:
a bottom electrical contact layer, and
a top electrical contact layer, said top electrical contact layer being transparent at the emission wavelength λ1, λ2 of the emitting layer in question.

Advantageously, each of the emitting layers comprises a set of nanowires oriented longitudinally in the direction z forming the active part of the emitting layer.

Thus, unlike the known solutions based on emitting layers having planar architectures, the emitting layers according to the present invention have three-dimensional architectures based on nanowires. In the superimposed planar architectures according to the prior art, the light emitted must pass through numerous planar interfaces perpendicular to the direction z. The light remains partly trapped by reflection on these planar interfaces. In the context of the development of the present invention, it has become clear that the three-dimensional architectures based on nanowires benefit from a directivity of emission in the direction z greater than that of the planar architectures. This limits the trapping of the light in or between the various emitting layers. The efficacy of extraction of the light is thus increased.

The nanowires are preferably arranged in one and the same emitting layer so as to form a photonic crystal. This further increases the directivity of emission of the emitting layer. The efficacy of extraction of the light is further increased.

Another aspect relates to an emissive screen comprising a plurality of pixels formed by optoelectronic devices according to the invention, disposed side by side in a plane transverse to the direction z.

Another aspect relates to a method of manufacturing such an optoelectronic device. Advantageously, the method comprises at least the following steps:
Forming on a first substrate a first set of nanowires configured to emit the first radiation at the first wavelength λ1,
Forming a first bonding layer for the first set of nanowires,
Forming on a second substrate a second set of nanowires configured to emit the second radiation at the second wavelength λ2,
Forming a second bonding layer for the second set of nanowires,
Putting the second bonding layer facing the first bonding layer,
Assembling the first and second sets of nanowires by adhesive bonding at the first and second bonding layers,
Removing at least one among the first and second substrates,
Forming a first bottom electrical contact layer and a first top electrical contact layer for the first set of nanowires,
Forming a second bottom electrical contact layer and a second top electrical contact layer for the second set of nanowires.

Thus the method advantageously makes it possible to manufacture the various sets of nanowires separately. The growth conditions required for forming these various sets are thus better controlled. Transferring the various sets by bonding advantageously makes it possible to form superimposed emitting layers.

Each set of nanowires can advantageously be formed by “full surface” growth, in a manner that is not localized on the substrate. During the transfer, a standard precision of alignment between the various sets is then perfectly sufficient. Transfer is thus facilitated.

On the other hand, in the context of a known solution of direct manufacture of the various sets side by side on one and the same substrate, the various sets are formed by successive localized growths. Great precision of alignment of the various growth and/or protection masks is then required, in particular for manufacturing micro-LEDs. Forming the second set may furthermore damage the first set formed. Solutions for protection and for management of the high growth temperatures must be implemented, which makes this type of method complex and difficult to make reliable. Successive formations of sets of nanowires superimposed one on the other on one and the same substrate, directly and without transfer, is an alternative solution that is not envisaged in the context of the present invention, for the reasons explained above.

Preferably, at least one from the first bottom and top electrical contact layers or the second bottom and top electrical contact layers is formed from the first and second bonding layers. This makes it possible to reduce the number of layers and/or method steps. The cost of the method is reduced.

The optoelectronic device and the method according to the present invention advantageously make it possible to form screens or microscreens with a pixel size less than or equal to 50 μm, or even less than or equal to 10 μm. Such screens furthermore benefit from high emission directivity, and from improved light-extraction efficacy. Such screens can advantageously be used in augmented-reality applications.

### BRIEF DESCRIPTION OF THE FIGURES

The aims, objects, as well as the features and advantages of the invention will appear better from the detailed description of embodiments thereof which are illustrated by the following accompanying drawings, wherein:

FIG. 1 schematically illustrates an optoelectronic device according to a first embodiment of the present invention.

FIG. 2 schematically illustrates an optoelectronic device according to a second embodiment of the present invention.

FIG. 3 schematically illustrates an optoelectronic device according to a third embodiment of the present invention.

FIGS. 4A and 4B illustrate schematically an electrical operation of an optoelectronic device according to the first and second embodiments of the present invention.

FIG. 4C illustrates schematically an electrical operation of an optoelectronic device according to the third embodiment of the present invention.

FIGS. 5A to 5H illustrate steps of a method for manufacturing the optoelectronic device illustrated in FIG. 1 according to one embodiment of the present invention.

FIGS. 6A to 6G illustrate steps of a method for manufacturing the optoelectronic device illustrated in FIG. 2 according to one embodiment of the present invention.

FIGS. 7A to 7G illustrate steps of a method for manufacturing the optoelectronic device illustrated in FIG. 3 according to one embodiment of the present invention.

The drawings are given as examples and do not limit the invention. They constitute schematic outline representations intended to facilitate understanding of the invention and are not necessarily plotted to the scale of practical applications. In particular, the dimensions of the various elements constituting the emitting layers are not necessarily representative of reality.

### DETAILED DESCRIPTION OF THE INVENTION

Before beginning a detailed review of embodiments of the invention, it is stated that the invention may in particular comprise the optional features hereafter, which may be used in association or alternatively:

According to one example, the first emitting layer comprises a first set of nanowires. The second emitting layer comprises a second set of nanowires. The third emitting layer comprises a third set of nanowires.

According to one example, the nanowires in the first set of nanowires are structurally different (for example in diameter and/or in grating pitch) from those in the second set of nanowires. The nanowires in the first set of nanowires are structurally different (for example in diameter and/or in grating pitch) from those in the third set of nanowires. The nanowires in the second set of nanowires are structurally different (for example in diameter and/or in grating pitch) from those in the third set of nanowires.

According to one example, the nanowires are arranged in one and the same emitting layer so as to form a photonic crystal. This makes it possible to increase the emission directivity of the radiation produced by the nanowires, in the longitudinal direction z. The efficacy of extraction is thus improved.

According to one example, the active parts of the emitting layers are disposed in a staircase, so that each of the sets of nanowires has at least a part not covered by the other sets of nanowires, on the emission side of the device. The active parts are thus at least partly not covered by other sets of nanowires. The extraction efficacy is thus improved. The lateral dimension of the pixel formed by the various emitting layers partly superimposed in the vertical direction z remains smaller than the dimension of the pixel formed by emitting layers adjacent in a lateral direction.

According to one example, for each emitting layer:
the bottom electrical contact layer is reflective at the emission wavelength λ1, λ2 of the emitting layer in question, and
the top electrical contact layer is transparent at the emission wavelength λ1, λ2 of the emitting layer in question.

The reflective bottom electrical contact layers make it possible to increase the flow of radiation towards the emission face of the device. The extraction efficacy is thus improved.

According to one example, the transparent top electrical contact layers are not surmounted by the sets of nanowires.

According to one example, in the device:
the bottom electrical contact layer located under all the active parts of the device is reflective at the emission wavelength λ1, λ2 of said active parts,
the other bottom electrical contact layers are transparent at the wavelengths λ1, λ2 of the active parts located under said other bottom electrical contact layers,
the top electrical contact layers are transparent at the wavelengths λ1, λ2 of the active parts located under said top electrical contact layers.

The transparent bottom and top electrical contact layers make it possible to superimpose various emitting layers while allowing the radiation coming from these emitting layers to pass.

According to one example, the bottom electrical contact layers are disposed facing a base side of the device.

According to one example, the top electrical contact layers are disposed facing an emission side of the device.

According to one example, all the bottom electrical contact layers are connected together. They can be put to the same electrical potential, for example to ground.

In one example, two active parts adjacent in the direction z share the same transparent electrical contact layer. This makes it possible to reduce the vertical size, along z, of the device. This also makes it possible to simplify the design and manufacture of the device.

According to one example, the top electrical contact layer of an emitting layer corresponds to the top electrical contact layer of another emitting layer located immediately above said emitting layer.

According to one example, at least some of the bottom and top electrical contact layers are connected by vias passing through at least one set of nanowires in the direction Z.

According to one example, the plurality of emitting layers comprises at least one third emitting layer comprising a third active part configured to emit a third radiation at a third wavelength λ3, with λ1≠λ2≠λ3, said third emitting layer comprising a third set of nanowires oriented longitudinally in the direction z and forming said third active part.

According to one example, the first emitting layer comprises a first set of nanowires configured to emit the first radiation at the first wavelength λ1.

According to one example, the second emitting layer comprises a second set of nanowires configured to emit the second radiation at the second wavelength λ2, with λ1≠λ2.

According to one example, the third emitting layer comprises a third set of nanowires configured to emit the third radiation at the third wavelength λ3, with λ1≠λ2≠λ3.

According to one example, the first, second and third sets of nanowires are stacked in the direction z and at least partly superimposed in projection along the direction z.

According to one example, the top electrical contact layers define the lateral dimensions of the LEDs or of the corresponding subpixels . This makes it possible to avoid physically delimiting the sets of nanowires by etching isolation trenches or by etching in accordance with a mesa structure for example.

According to one example, the bottom electrical contact layers are deposited over the full surface. This simplifies the method for manufacturing optoelectronic devices.

According to one example, the first and second bonding layers comprise respectively first and second metal layers, the first and second sets of nanowires are assembled by thermal bonding of said first and second metal layers.

According to one example, said first and second metal layers form the first bottom electrical contact layer.

According to one example, the method furthermore comprises, after the first substrate is assembled and removed:
an etching of part of the first set of nanowires and of the first and second bonding layers, so as to expose part of the second set of nanowires,
a deposition of a transparent conductive layer of oxide on the exposed part of the second set of nanowires, so as to form the second top electrical contact layer.

According to one example, the method furthermore comprises the deposition of a transparent encapsulation layer on the layer of transparent conductive oxide on the exposed part of the second set of nanowires. The encapsulation layer makes it possible to integrate the staircase device in compact chips or systems. The fact that it is transparent makes it possible to keep good light efficacy.

According to one example, the first and second bonding layers comprise respectively first and second transparent dielectric layers, the first and second sets of nanowires being assembled by molecular bonding of said first and second transparent dielectric layers.

According to one example, the first and second transparent dielectric layers form a dielectric layer interposed between the first bottom electrical contact layer and the second top electrical contact layer.

According to one example, the first and second bonding layers comprise respectively first and second transparent conductive layers of oxide, the first and second sets of nanowires being assembled by molecular bonding of said first and second transparent conductive layers of oxide.

According to one example, the first and second transparent conductive layers of oxide form both the first bottom electrical contact layer and the second bottom electrical contact layer.

Unless incompatible, technical features described in detail for a given embodiment may be combined with the technical features described in the context of other embodiments described for exemplary and non-limiting purposes, so as to form another embodiment which is not necessarily illustrated or described. Of course, such an embodiment is not excluded from the invention.

“Optoelectronic device” is taken to mean a device suited to emitting, conveying, or receiving light. According to one particular application, such an optoelectronic device comprises light emitting diodes (LEDs), in particular LEDs forming the sub-pixels of an emissive-screen pixel.

The invention may be implemented more broadly for different optoelectronic devices. The invention may for example be implemented in the context of laser or photovoltaic devices.

LEDs or optoelectronic devices typically have, within the scope of the present invention, dimensions, in projection in a base plane xy, less than 100 μm×100 μm, preferably less than 10 μm×10 μm.

Unless explicitly stated, it is specified that, within the scope of the present invention, the relative disposition of a second layer intercalated between a first layer and a third layer does not necessarily mean that the layers are directly in contact with each other, but means that the second layer is either directly in contact with the first and third layers, or separated therefrom by at least one other layer or at least one other element.

Thus, the terms and phrases “bear on”, “surmount”, “cover” or “overlap” do not necessarily mean “in contact with”.

The steps of the method as claimed should be understood in the broad sense and can optionally be implemented in several sub-steps.

In the present patent application, the terms “light-emitting diode”, “LED” or simply “diode” are used as synonyms. An “LED” may also be understood as a “micro-LED”.

In the context of the present invention, the sets of nanowires belong to different emitting layers and are distinct from each other. These sets of nanowires cannot be arbitrarily defined as subparts of a single assembly. Several junctions formed in one and the same nanowire do not structurally form several distinct nanowires.

A substrate, a layer, a device, “based on” a material M is taken to mean a substrate, a layer, a device comprising only this material M or this material M and possibly other materials, for example alloying elements, impurities or doping elements. Thus a GaN-based diode typically comprises GaN and AlGaN or InGaN alloys.

A reference frame, preferably orthonormal, comprising the axes x, y, z is shown in certain appended figures. This reference frame is applicable by extension to the other figures of the same plate of figures.

In the present patent application, thickness will preferentially be spoken of for a layer and height for a structure or a device. The thickness is considered along a direction normal to the main extension plane of the layer, and the height is considered perpendicularly to the base plane xy. Thus a layer typically has a thickness along z when it extends mainly along a plane xy, and a projecting element, for example a nanowire, has a height along z. The relative terms “on”, “under”, and “underlying” preferentially refer to positions considered in the direction z. In the present application, “vertical” and “vertically” mean “directed in the direction z” and “lateral” and “laterally” mean “directed in a direction of the plane xy”.

Within the scope of the present invention, a “transparent” object or material means that the object or the material allows at least 90% of the light intensity of the light beam that passes through it to pass. A surface is considered to be “reflective” provided that it retransmits at least 85% of the intensity of an incident light beam. The reflection may be specular (one reflection direction) or diffuse (several reflection directions).

The dimensional values should be understood considering the manufacturing and measurement tolerances.

The terms “substantially”, “about”, “of the order of” mean, when they relate to a value, “to within 10%” of this value or, when they relate to an angular orientation, “to within 10°” of this orientation. Thus a direction substantially normal to a plane means a direction having an angle of 90±10°with respect to the plane.

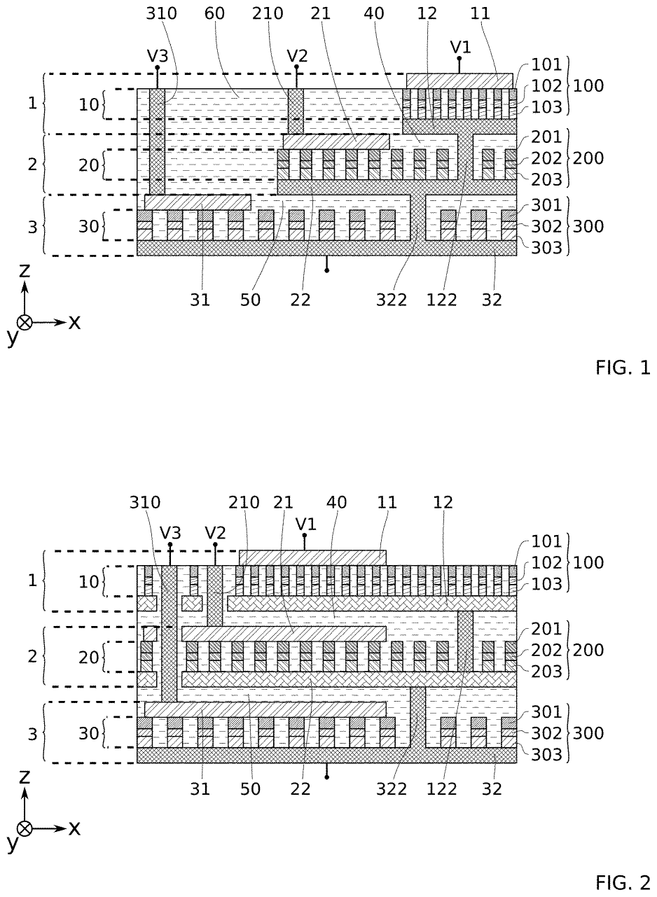

FIGS. 1, 2 and 3 illustrate various embodiments of an optoelectronic device comprising three emitting layers 1, 2, 3.

Each emitting layer typically comprises a set of nanowires configured to emit a light radiation at a particular wavelength λ. Each set of nanowires comprises a plurality of semiconductor nanowires preferably mainly directed along z, embedded in a matrix based on a dielectric material. The semiconductor nanowires typically each comprise an active region interposed between an electron injection region and a hole injection region. The active region emits light radiation with a wavelength λ by radiative recombination of the electrons and holes.

According to one possibility, all the nanowires in a given set of nanowires have substantially identical diameters. According to one possibility, all the nanowires in a given set of nanowires are separated from each other by a separation distance that is approximately constant in a given direction of the plane xy. The positions of the nanowires in a given set of nanowires are preferably distributed in an ordered lattice. The diameters and positions of the nanowires in a given set of nanowires are preferably selected so that all the nanowires form a photonic crystal. The arrangement of the nanowires as a photonic crystal makes it possible to optimize the extraction of light from the set of nanowires. The light radiation of such a set of nanowires arranged as a photonic crystal has increased directivity along z.

Preferably, the first emitting layer 1 comprises a first set 10 of nanowires 100 configured to emit the light radiation of wavelength λ1 with λ1 corresponding to a substantially blue visible wavelength. The nanowires 100 in the set 10 typically each comprise an electron-injection region 101, an active region 102, and a hole-injection region 103. The nanowires 100 are for example based on GaN, AlGaN or InGaN. These nanowires 100 are preferably distributed in the set 10 as a photonic crystal optimized for the wavelength λ1. The first emitting layer 1 furthermore comprises a first top electrical contact layer 11 on the first set 10 of nanowires 100 and a first bottom electrical contact layer 12 under the first set 10 of nanowires 100. The first top and bottom electrical contact layers 11, 12 connect at least some nanowires 100 in the first set 10, respectively at the electron and hole injection regions 101, 103.

Preferably, the second emitting layer 2 comprises a second set 20 of nanowires 200 configured to emit the light radiation of wavelength λ2 with λ2≠λ1, and λ2 corresponding to a substantially green visible wavelength. The nanowires 200 in the set 20 typically each comprise an electron-injection region 201, an active region 202, and a hole-injection region 203. The nanowires 200 are for example based on GaN, AlGaN or InGaN. These nanowires 200 are preferably distributed in the set 20 as a photonic crystal optimized for the wavelength λ2. The second emitting layer 2 furthermore comprises a second top electrical contact layer 21 on the second set 20 of nanowires 200 and a second bottom electrical contact layer 22 under the second set 20 of nanowires 200. The second top and bottom electrical contact layers 21, 22 connect at least some nanowires 200 in the second set 20, respectively at the electron and hole injection regions 201, 203.

Preferably, the third emitting layer 3 comprises a third set 30 of nanowires 300 configured to emit the light radiation of wavelength λ3 with λ3≠λ2≠λ1, and λ3 corresponding to a substantially red visible wavelength. The nanowires 300 in the set 30 typically each comprise an electron-injection region 301, an active region 302, and a hole-injection region 303. The nanowires 300 are for example based on GaN, AlGaN or InGaN. These nanowires 300 are preferably distributed in the set 30 as a photonic crystal optimized for the wavelength λ3. The third emitting layer 3 furthermore comprises a third top electrical contact layer 31 on the third set 30 of nanowires 300 and a third bottom electrical contact layer 32 under the third set 30 of nanowires 300. The third top and bottom electrical contact layers 31, 32 connect at least some nanowires 300 in the third set 30, respectively at the electron and hole injection regions 301, 303.

Hereinafter, various arrangements of these emitting layers 1, 2, 3 in the optoelectronic device are described. The electronic device preferably has an emission side, turned towards the top on the accompanying figures, and a base side opposite to the emission side and turned towards the bottom on the accompanying figures.

FIG. 1 illustrates an optoelectronic device comprising three emitting layers 1, 2, 3 stacked along z and partially superimposed. In this first embodiment, the emitting layers 1, 2, 3 are staged with respect to each other, in a staircase configuration. Thus the third emitting layer 3 is surmounted by the second emitting layer 2, offset laterally, which forms a step, and the second emitting layer 2 is surmounted by the first emitting layer 1, offset laterally, which forms another step. This staging in a staircase makes it possible to leave clear the active parts of the various emitting layers 1, 2, 3, i.e. the parts that effectively emit respectively the radiations of wavelengths λ1, λ2, λ3. An active part is thus typically formed by one or more nanowires electrically connected both at their electron-injection regions and at their hole-injection regions. In this first embodiment, the active part of an emitting layer is not surmounted by other sets of nanowires or other parts of the other emitting layers. This makes it possible to optimize the light extraction of the device, in particular on the emission side of the device.

In this first embodiment, the bottom electrical contact layers 12, 22, 32 preferably extend respectively under all the nanowires 100, 200, 300 of each of the sets 10, 20, 30. The bottom electrical contact layers 12, 22, 32 are typically metal and form reflectors for the radiations of wavelength λ1, λ2, λ3. A radiation emitted in the direction of the base side is thus advantageously reflected in the direction of the emission side of the device. This makes it possible to optimize the light extraction on the emission side of the device.

In this first embodiment, the top electrical contact layers 11, 21, 31 preferably extend respectively only over part of the nanowires 100, 200, 300 of each of the sets 10, 20, 30. In particular, the top electrical contact layer 31 extends over the nanowires 300 that are not surmounted by nanowires 200 and by nanowires 100. The top electrical contact layer 21 extends over the nanowires 200 that are not surmounted by nanowires 100. The top electrical contact layers 11, 21, 31 are typically based on transparent conductive oxide, for example based on ITO (indium tin oxide). They are transparent at least respectively for the radiations of wavelength λ1, λ2, λ3. The top electrical contact layers 11, 21, 31 define substantially the respective active parts of the emitting layers 1, 2, 3.

In this first embodiment, the bottom electrical contact layers 12, 22, 32 are preferably connected together by vias 122, 322. They can thus be put to the same electrical potential. The first bottom electrical contact layer 12 is connected to the second bottom electrical contact layer 22 by one or more vias 122. The second bottom electrical contact layer 22 is connected to the third bottom electrical contact layer 32 by one or more vias 322. The first bottom electrical contact layer 12 is separated from the second set 20 of nanowires 200 by an intermediate dielectric layer 40. The second bottom electrical contact layer 22 is separated from the third set 30 of nanowires 300 by an intermediate dielectric layer 50.

In this first embodiment, the active parts left clear form steps that can be covered by an encapsulation layer 60 transparent at the wavelengths λ1, λ2 and/or λ3. This makes it possible to obtain a device having a substantially planar and horizontal surface, which can easily be integrated in a chip or an electronic system. Vias 210, 310 can pass through this encapsulation layer 60 to respectively connect the top electrical contact layers 21, 31. In this first embodiment, all the electron injection regions 101, 201, 301 are preferably disposed on the same side, for example on the emission side of the device, as illustrated in FIG. 1. The LEDs formed by the emitting layers 1, 2, 3 thus all have the same passing direction for the current.

FIG. 2 illustrates a second embodiment of the optoelectronic device. In this second embodiment, the emitting layers 1, 2, 3 are superimposed along z. Thus the lateral size of the device is reduced. In the case of emitting layers corresponding to subpixels, the lateral dimension of the pixels comprising the subpixels decreases, and the resolution of the screen can be augmented. In this second embodiment, the active parts of the emitting layers are superimposed on each other. This makes it possible to obtain a native color mixing for a pixel having such an architecture. The photonic-crystal effects are furthermore reinforced by the nanowires laterally adjacent to the various active parts.

Preferably, the emitting layer 3 emitting in the red is surmounted by the emitting layer 2 emitting in the green, and the emitting layer 2 emitting in the green is surmounted by the emitting layer 1 emitting in the blue, in the direction of the emission side of the device. This makes it possible to minimize the optical interactions between the various light radiations when they are propagated towards the emission side of the device.

In this second embodiment, the bottom electrical contact layers 12, 22, 32 preferably extend respectively under all the nanowires 100, 200, 300 of each of the sets 10, 20, 30. The bottom electrical contact layer 32 disposed on the base side of the device is typically metal and forms a reflector for the radiations of wavelength λ1, λ2, λ3. A radiation emitted in the direction of the base side is thus advantageously reflected in the direction of the emission side of the device. This makes it possible to optimize the light extraction on the emission side of the device. The bottom electrical contact layers 12, 22 are typically based on transparent conductive oxide. This makes it possible to let pass the radiation emitted by the underlying emitting layer, in the direction of the emission side of the device.

In this second embodiment, the top electrical contact layers 11, 21, 31 preferably extend respectively only over part of the nanowires 100, 200, 300 of each of the sets 10, 20, 30. The top electrical contact layers 11, 21, 31 are typically based on transparent conductive oxide, for example based on ITO (indium tin oxide). They are transparent for the radiations of wavelength λ1, λ2, λ3. The top electrical contact layers 11, 21, 31 define substantially the respective active parts of the emitting layers 1, 2, 3, and therefore the lateral dimensions of the corresponding subpixels.

In this second embodiment, vias 210, 310 can pass through the first and second sets 10, 20 of nanowires 100, 200 to respectively connect the top electrical contact layers 21, 31. The bottom electrical contact layers 12, 22, 32 are preferably connected together by vias 122, 322. The first bottom electrical contact layer 12 is separated from the second top electrical contact layer 21 by an intermediate dielectric layer 40. The second bottom electrical contact layer 22 is separated from the third top electrical contact layer 31 by an intermediate dielectric layer 50.

In this second embodiment, all the electron injection regions 101, 201, 301 are preferably disposed on the same side, for example on the emission side of the device, as illustrated in FIG. 2. The LEDs formed by the emitting layers 1, 2, 3 thus all have the same passing direction for the current.

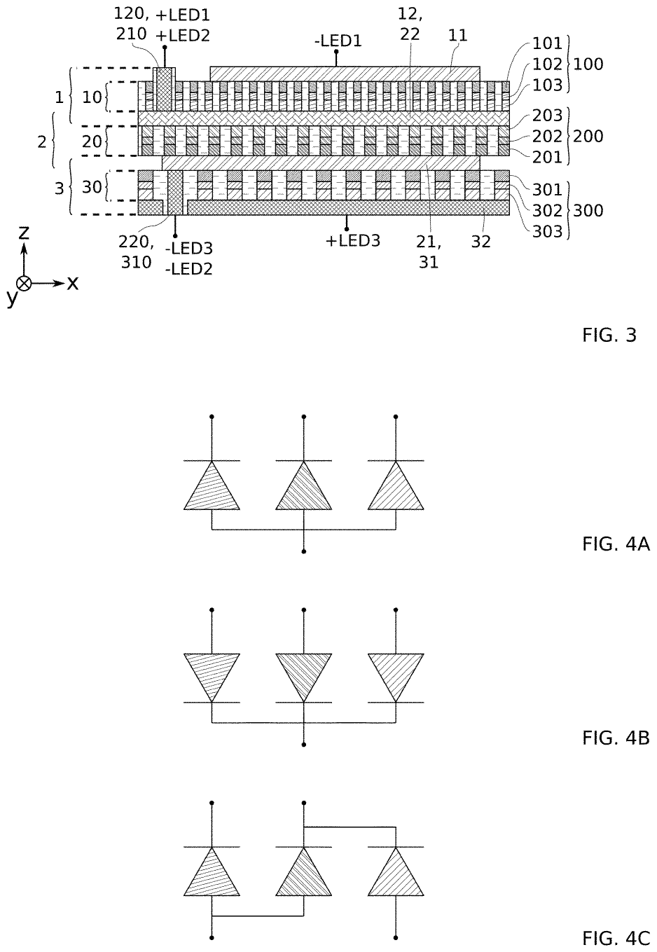

FIG. 3 illustrates a third embodiment of the optoelectronic device. In this third embodiment, the emitting layers 1, 2, 3 are superimposed along z and share at least one bottom and/or top electrical contact layer with the adjacent emitting layer or layers. This makes it possible to reduce the vertical size of the device. This also makes it possible to simplify the design of the device and to reduce the manufacturing costs of the device. As with the second embodiment, this architecture makes it possible to obtain a native color mixing for the pixel. The photonic-crystal effects are furthermore reinforced. The emitting layers are preferably stacked from the base side of the device is far as the emission side of the device, according to the respective emission wavelengths red, green, blue.

In this third embodiment, the bottom electrical contact layers 12, 22, 32 preferably extend respectively on or under all the nanowires 100, 200, 300 of each of the sets 10, 20, 30. The bottom electrical contact layer 32 disposed on the base side of the device is typically metal and forms a reflector for the radiations of wavelength λ1, λ2, λ3. A radiation emitted in the direction of the base side is thus advantageously reflected in the direction of the emission side of the device. The top electrical contact layers 11, 21, 31 preferably extend respectively only over part of the nanowires 100, 200, 300 of each of the sets 10, 20, 30. They are transparent for the radiations of wavelength λ1, λ2, λ3.

In this third embodiment, the bottom electrical contact layers 12, 22 typically form a single layer based on transparent conductive oxide. The top electrical contact layers 21, 31 typically form a single base layer of transparent conductive oxide, for example based on ITO (indium tin oxide). In this third embodiment, there are no dielectric intermediate layers between the electrical contact layers 12, 22 on the one hand and between the electrical contact layers 21, 31 on the other hand.

In this third embodiment, the electron injection regions 101, 301 of the first and third sets 10, 30 of nanowires 100, 300 are preferably disposed on the same side, for example on the emission side of the device, as illustrated in FIG. 3. The electron injection regions 201 of the second set 20 of nanowires 200 are preferably disposed on the same side, for example on the base side of the device, as illustrated in FIG. 3. In this embodiment, the LEDs formed by the emitting layers 1, 2, 3 do not all have the same passing direction for the current.

In this third embodiment, vias 120, 210 can pass through the first set 10 of nanowires 100 to connect the bottom electrical contact layers 12, 22. The bottom electrical contact layers 12, 22 can thus be put to the same electrical potential. Vias 220, 310 can pass through the third set 30 of nanowires 300 to connect the top electrical contact layers 21, 31. The top electrical contact layers 21, 31 can thus be put to the same electrical potential.

FIGS. 4A, 4B, 4C illustrate the various electrical configurations allowed by the devices according to the various embodiments described above. FIGS. 4A, 4B illustrate two configurations of light-emitting diodes in parallel, with a common contact, which can be implemented from the first and second embodiments of the device described above. FIG. 4C illustrates a configuration of light-emitting diodes with passing directions in alternation, which can be implemented from the third embodiment of the device described above. In this case, the LEDs are typically activated successively one after the other. A duty factor for operation or switching on can be defined for the various LEDs of a pixel having this architecture.

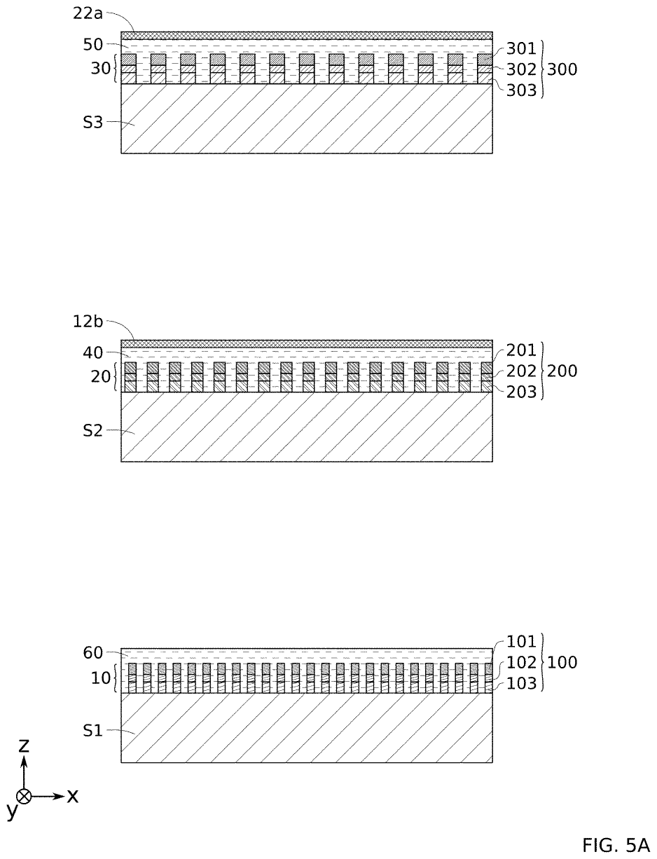

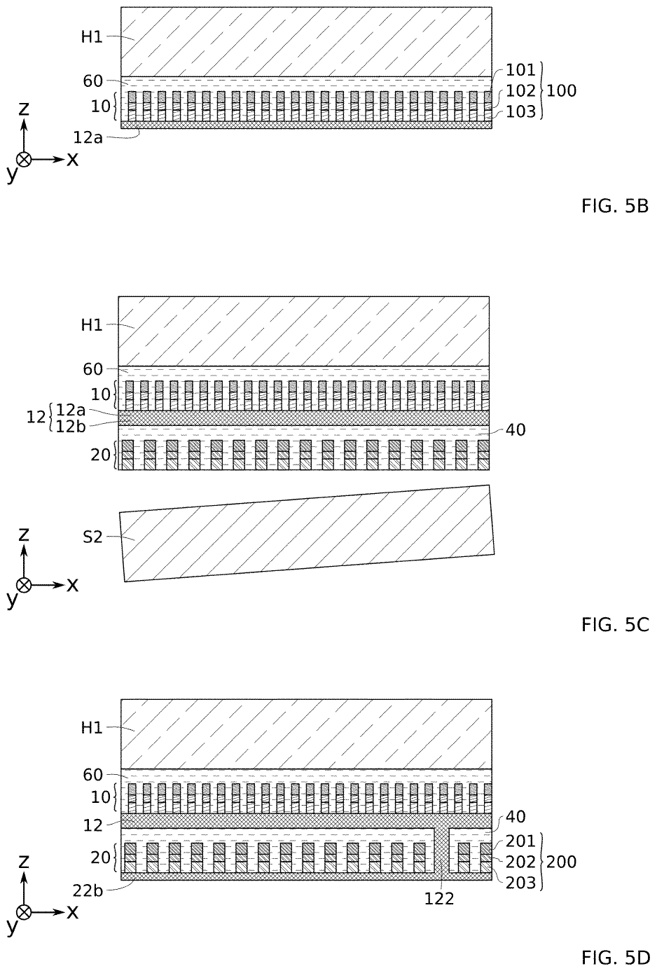

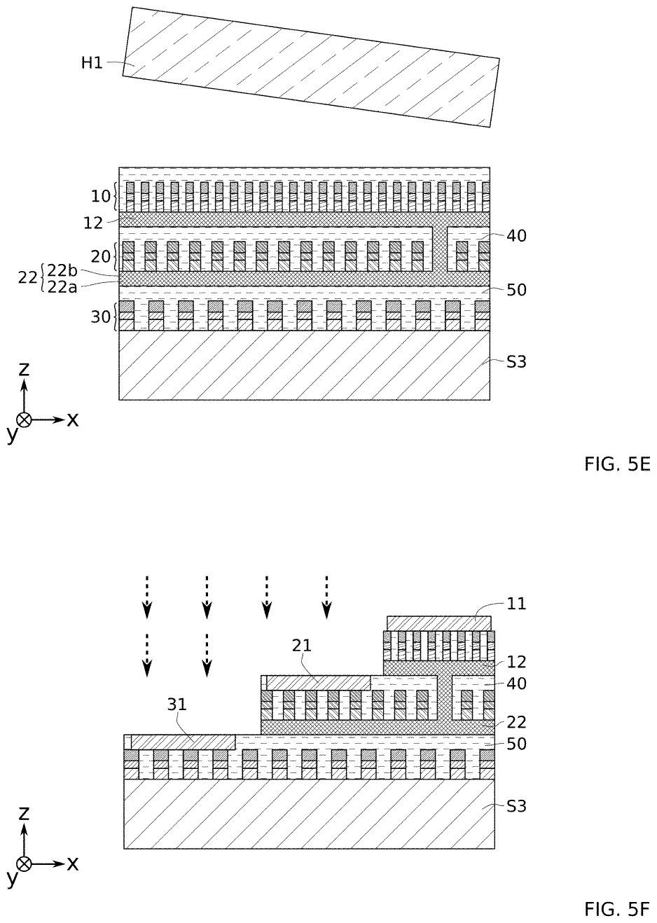

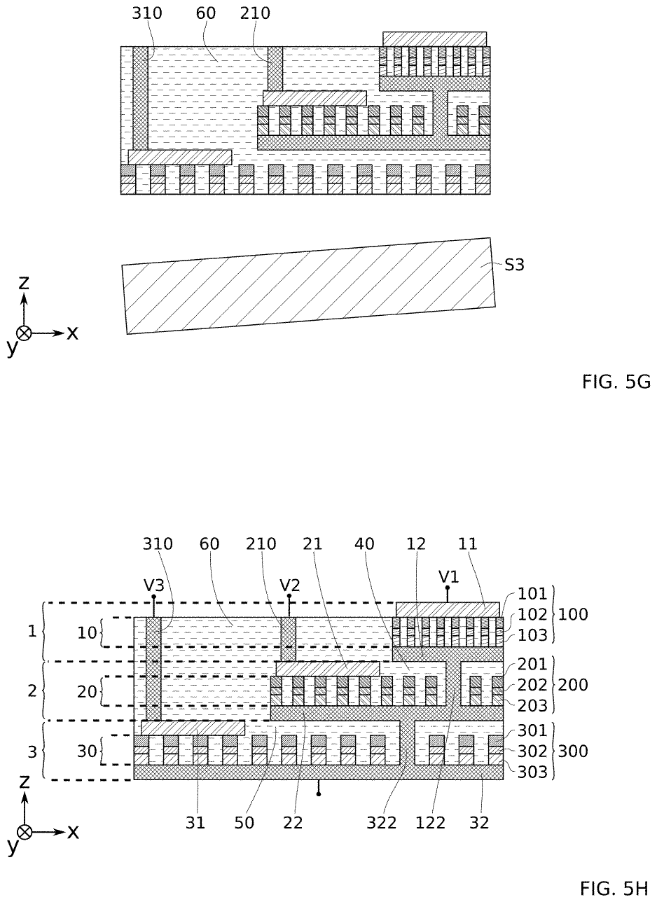

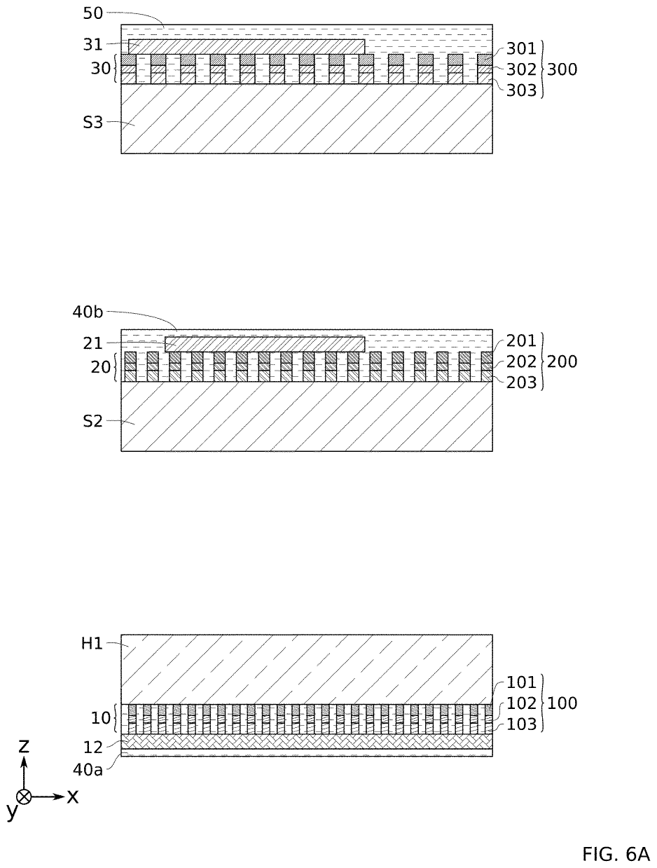

FIGS. 5A to 5H illustrate steps of manufacturing an optoelectronic device illustrated in FIG. 1.

As illustrated in FIG. 5A, the first step consists in separately forming the various sets 10, 20, 30 of nanowires on distinct substrates S1, S2, S3. In a known manner, the substrates S1, S2, S3 can typically each comprise a support, for example made from silicon, a buffer layer based on GaN, a nucleation layer based on AlN and/or a masking layer based on a dielectric material, for example made from silicon nitride Si₃N₄. The masking layer makes it possible in particular to grow the nanowires in a localized manner on the substrate, in accordance with a method called SAG (the acronym of “selective area growth”), preferably in an ordered lattice in order to form a photonic crystal.

The nanowires 100, 200, 300 are preferably epitaxed respectively on the substrates S1, S2, S3, for example by metalorganic vapor phase epitaxy (MOVPE) or by molecular beam epitaxy (MBE).

The nanowires 100, 200, 300 are based on a semiconductor material, preferably based on III-V materials, for example based on GaN, AlGaN or InGaN. They may alternatively be based on II-VI materials, for example based on ZnO or ZnSe, or based on IV-IV materials, for example based on Si or SiGe.

The nanowires 100, 200, 300 preferably extend longitudinally along z. They can have a height of between a few tens of nanometer and several micrometers, for example between 100 nm and 20 μm. They can have various forms, in cross section in the plane xy. The nanowires 100, 200, 300 based on GaN typically have a substantially hexagonal cross-section. The maximum dimension of the nanowires in the plane xy, for example the diameter, can be between a few tens of nanometers and several micrometers, for example between 50 nm and 5 μm. They are preferably substantially parallel to each other and regularly distributed on the substrates S1, S2, S3. They can be encapsulated in a matrix based on a dielectric material such as silicon dioxide or silicon nitride. This makes it possible to protect the nanowires 100, 200, 300. This also makes it possible to improve the mechanical strength of the lattices of nanowires 100, 200, 300 on their respective substrates S1, S2, S3. The nanowires are here preferably formed with the hole injection regions 103, 203, 303 on the same side as the substrates S1, S2, S3.

After growth and encapsulation of the nanowires 100, 200, 300, a planarization step, for example by chemical mechanical polishing (CMP), is typically implemented so as to obtain a planar surface lying flush with the top of the electron injection regions 101, 201, 301.

Dielectric intermediate layers 40, 50, 60 are next formed on the planarized surfaces of the sets 10, 20, 30 of nanowires 100, 200, 300, for example by chemical vapor deposition (CVD). The dielectric intermediate layers 40, 50 are next covered by metal bonding layers 12b, 22a, typically by a full-surface deposition method. The metal bonding layers 12b, 22a can be based on aluminum, silver, and/or goals.

As illustrated in FIG. 5B, a manipulation substrate H1 is assembled by bonding to the set 10 of nanowires 100, by means of the dielectric intermediate layer 60. The substrate S1 is next removed and a metal bonding layer 12a is formed at the hole injection regions 103, preferably full surface.

As illustrated in FIG. 5C, the sets 10, 20 of nanowires 100, 200 are next assembled by metal-metal bonding between the bonding layers 12a, 12b, for example by Au—Au thermocompression for bonding layers 12b, 12a based on gold. The bonding layers 12a, 12b deposited on the full surface allow a tolerance of alignment between the sets 10, 20 of nanowires 100, 200. The bonding layers 12a, 12b advantageously form the first bottom electrical contact layer 12. The substrate S2 is next removed.

As illustrated in FIG. 5D, a metal bonding layer 22b is formed at the hole injection regions 203, preferably full surface. One or more vias 122 can be formed through the set 20 of nanowires 200 so as to electrically connect the bonding layer 22b to the first bottom electrical contact layer 12.

As illustrated in FIG. 5E, the sets 20, 30 of nanowires 200, 300 are next assembled by metal-metal bonding between the bonding layers 22a, 22b, for example by Au—Au thermocompression for bonding layers 22b, 22a based on gold. The bonding layers 22a, 22b deposited on the full surface allow a tolerance of alignment between the sets 20, 30 of nanowires 200, 300. The bonding layers 22a, 22b advantageously form the second bottom electrical contact layer 22. The manipulation substrate H1 is next removed.

As illustrated in FIG. 5F, a first localized etching or series of etchings is implemented so as to expose part of the set 20 of nanowires 200. A second localized etching or series of etchings is next implemented so as to expose part of the set 30 of nanowires 300. These successive etchings are configured so as to obtain a staircase structure of the sets 30, 20, 10 of nanowires 300, 200, 100. After etchings, the top electrical contact layers 11, 21, 31 based on transparent conductive oxide are formed on the exposed parts of the sets 10, 20, 30 of nanowires 100, 200, 300.

As illustrated in FIG. 5G, the staircase structure can be encapsulated by a transparent encapsulation layer 60 and then planarized. Vias 210, 310 can be formed through this encapsulation layer 60 to electrically connect the top electrical contact layers 21, 31. The substrate S3 can next be removed or thinned.

As illustrated in FIG. 5H, after removal of the substrate S3, the third metal bottom electrical contact layer 32 can be formed at the hole injection regions 303. According to a possibility that is not illustrated, the substrate S3 is electrically conductive and is not completely removed. It is thinned to directly form the third bottom electrical contact layer 32. One or more vias 322 can next be formed through the set 30 of nanowires 300 so as to electrically connect the third bottom electrical contact layer 32 to the second bottom electrical contact layer 22.

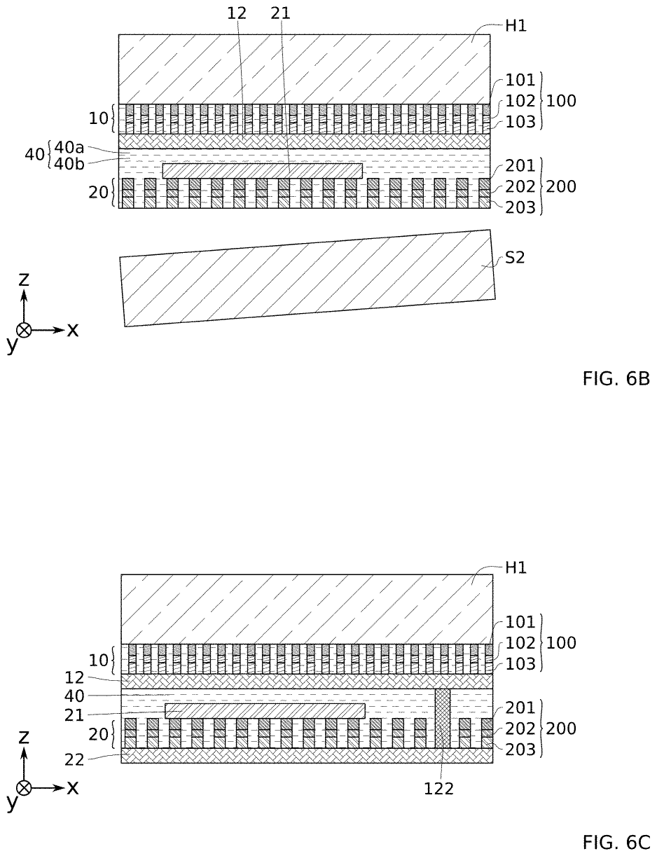

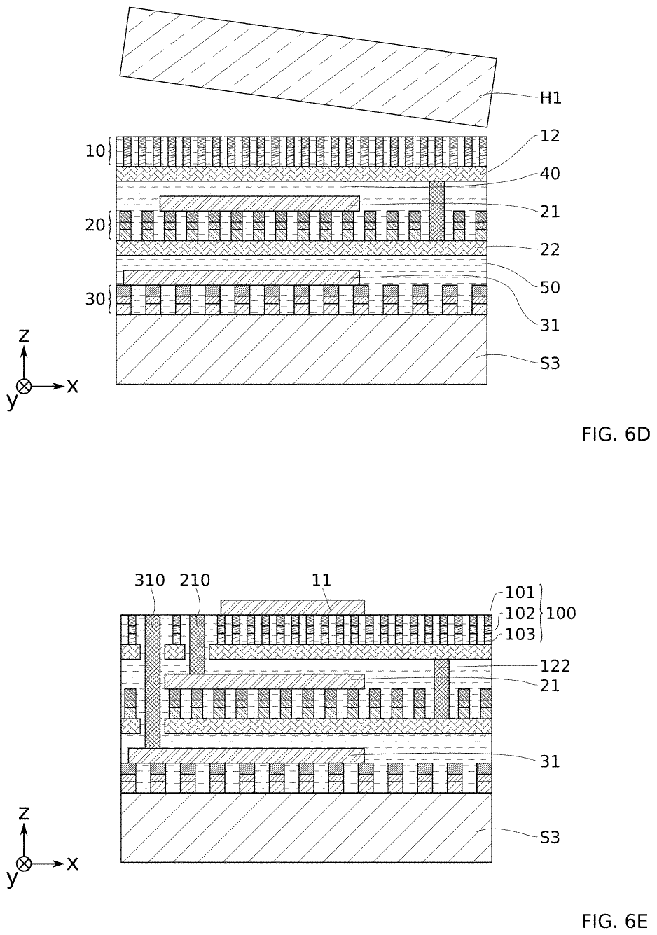

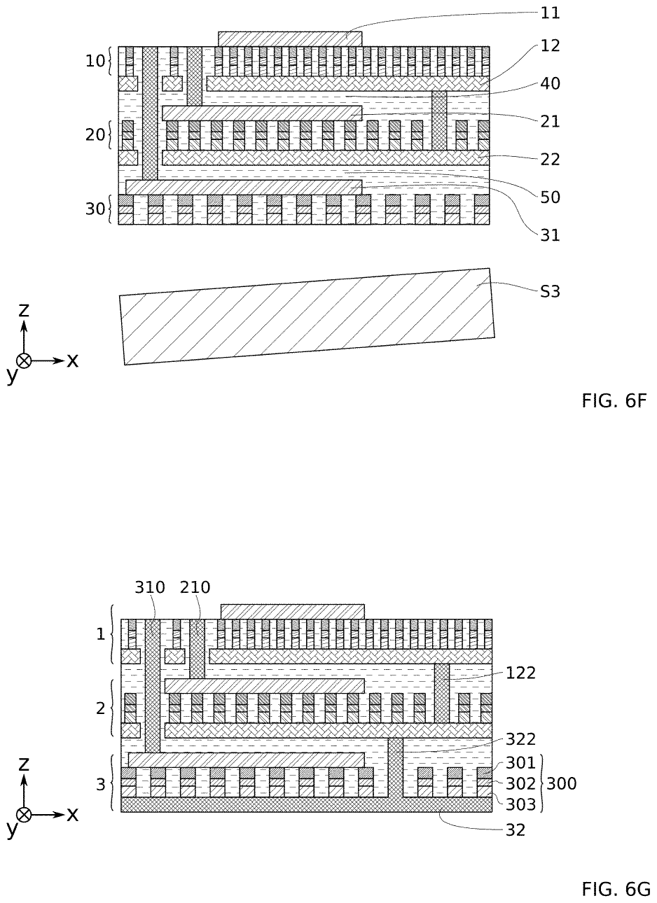

FIGS. 6A to 6G illustrate steps of manufacturing an optoelectronic device illustrated as in FIG. 2, according to another embodiment of the invention.

As illustrated in FIG. 6A, the first step consists in separately forming the various sets 10, 20, 30 of nanowires on distinct substrates S1, S2, S3. As before, a manipulation substrate H1 is assembled on the set 10 of nanowires 100, and the substrate S1 is removed.

The top electrical contact layers 21, 31 based on transparent conductive oxide are formed on the planarized surfaces of the sets 20, 30 of nanowires 200, 300, and then covered by bonding layers 40b, 50 typically based on a dielectric material such as silicon oxide. The first bottom electrical contact layer 12 based on transparent conductive oxide is preferably formed over the entire surface at the hole injection regions 103, and a bonding layer 40a similar to the bonding layers 40b, 50 is formed on the first bottom electrical contact layer 12.

As illustrated in FIG. 6B, the sets 10, 20 of nanowires 100, 200 are next assembled by oxide-oxide bonding between the bonding layers 40a, 40b, for example by molecular bonding. The bonding layers 40a, 40b deposited on the full surface allow a tolerance of alignment between the sets 10, 20 of nanowires 100, 200. The bonding layers 40a, 40b advantageously form the dielectric intermediate layer 40. The substrate S2 is next removed.

As illustrated in FIG. 6C, the second bottom electrical contact layer 22 based on transparent conductive oxide is preferably formed over the full surface at the hole injection regions 203. A thin layer of oxide (not illustrated) can be formed on the second bottom electrical contact layer 22 so as to facilitate subsequent bonding. One or more vias 122 can be formed through the set 20 of nanowires 200 so as to electrically connect the second bottom electrical contact layer 22 to the first bottom electrical contact layer 12.

As illustrated in FIG. 6D, the sets 20, 30 of nanowires 200, 300 are next assembled by oxide-oxide bonding between the layers 22, 50. The manipulation substrate H1 is next removed.

As illustrated in FIG. 6E, after removal of the manipulation substrate H1, the first top electrical contact layer 11 based on transparent conductive oxide is formed at the electron injection regions 101. The various top electrical contact layers 11, 21, 31 are substantially vertically in line with each other, aligned with respect to each other for example at one of the lateral ends thereof. Vias 210, 310 are typically formed through the first and second sets 10, 20 of nanowires 100, 200 to respectively connect the top electrical contact layers 21, 31.

As illustrated in FIG. 6F, the substrate S3 can next be removed.

As illustrated in FIG. 6G, after removal of the substrate S3, the third metal bottom electrical contact layer 32 can be formed at the hole injection regions 303. One or more vias 322 can next be formed through the set 30 of nanowires 300 so as to electrically connect the third bottom electrical contact layer 32 to the second bottom electrical contact layer 22.

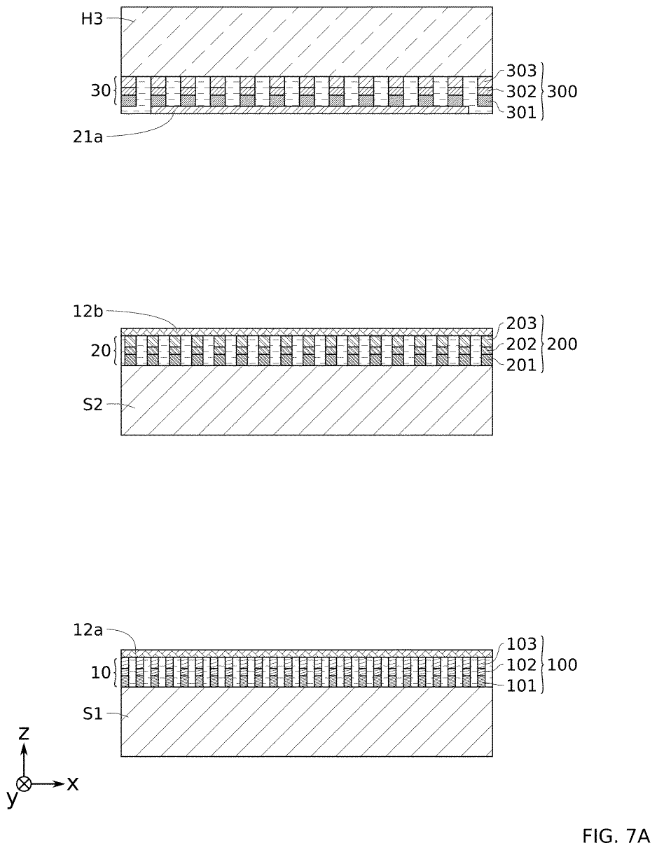

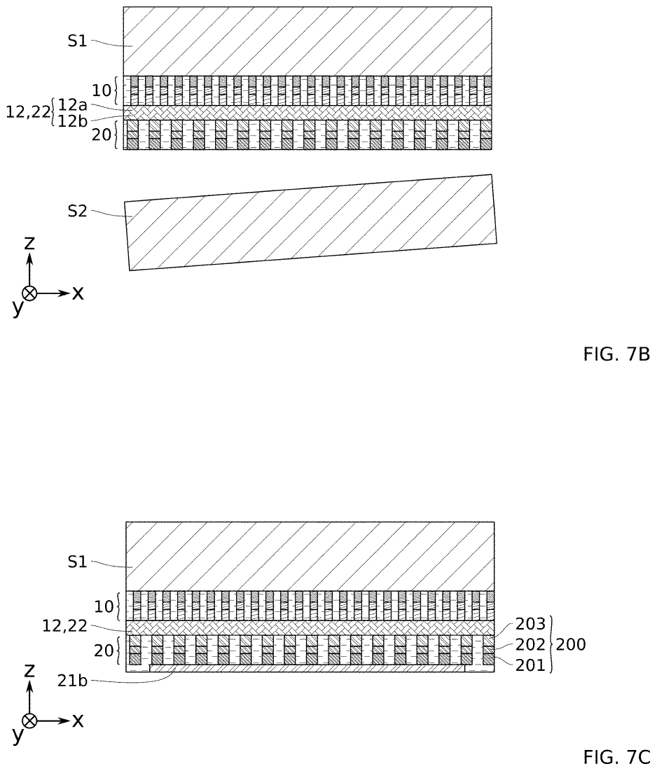

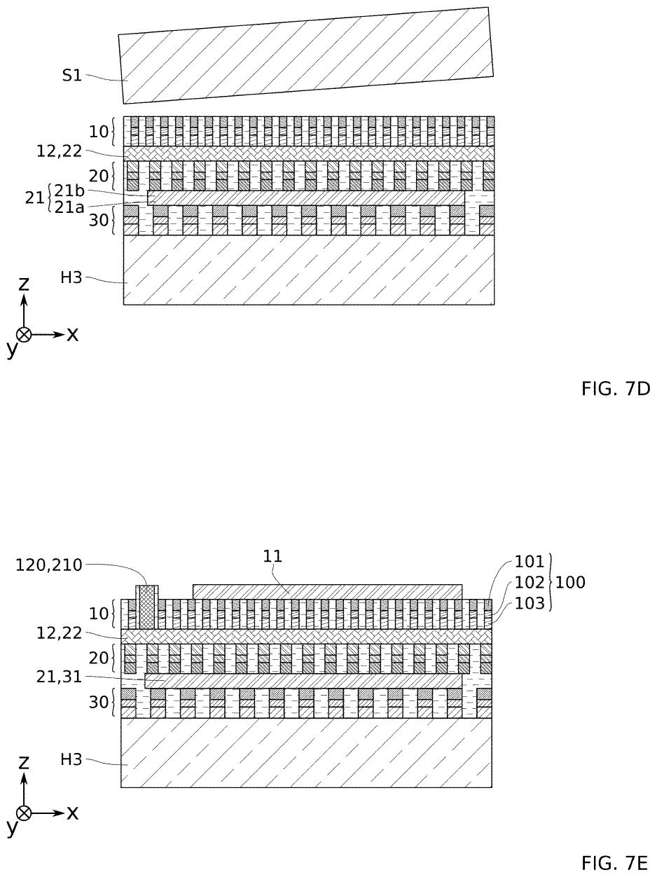

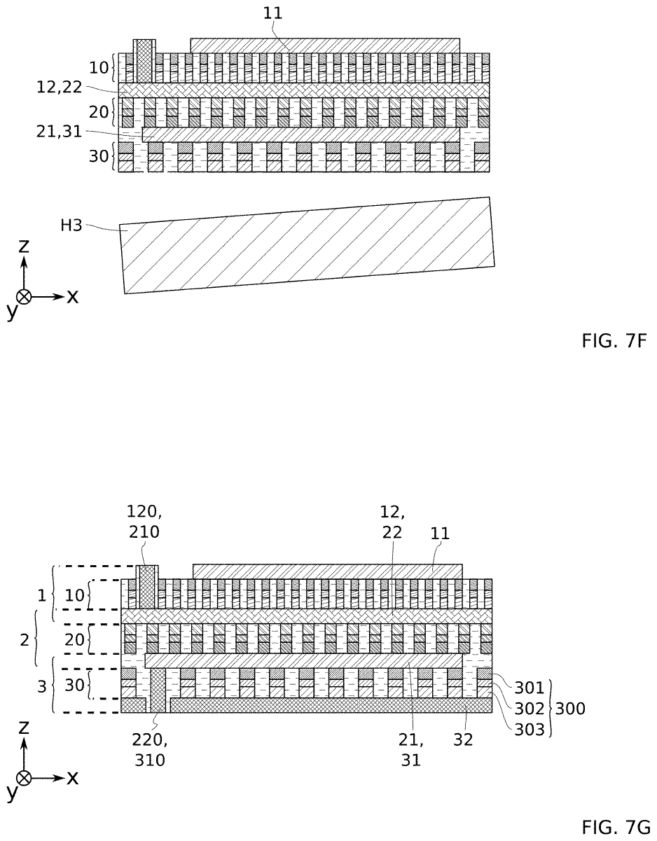

FIGS. 7A to 7G illustrate steps of manufacturing an optoelectronic device illustrated as in FIG. 3, according to another embodiment of the invention.

As illustrated in FIG. 7A, the first step consists in separately forming the various sets 10, 20, 30 of nanowires on distinct substrates S1, S2, S3. The nanowires are here preferably formed with the electron injection regions 101, 102, 103 on the same side as the substrates S1, S2, S3. In a similar manner to the embodiments described previously, a manipulation substrate H3 is assembled on the set 30 of nanowires 300, and the substrate S3 is removed. A bonding layer 21a based on transparent conductive oxide is formed at the electron injection regions 301. A bonding layer 12b based on transparent conductive oxide is formed on the planarized surface of the set 20 of nanowires 200, preferably over the full surface, at the hole injection regions 203. A bonding layer 12a based on transparent conductive oxide is formed on the planarized surface of the set 10 of nanowires 100, preferably over the full surface, at the hole injection regions 103.

As illustrated in FIG. 7B, the sets 10, 20 of nanowires 100, 200 are next assembled by oxide-oxide bonding between the bonding layers 12a, 12b, for example by molecular bonding. In this embodiment, the substrate S1 carrying the set 10 of nanowires 100 is turned over so as to put the bonding layers 12a, 12b facing each other. The bonding layers 12a, 12b deposited on the full surface allow a tolerance of alignment between the sets 10, 20 of nanowires 100, 200. In this embodiment, the bonding layers 12a, 12b advantageously form both the first bottom electrical contact layer 12 and the second bottom electrical contact layer 22. The substrate S2 is next removed.

As illustrated in FIG. 7C, a bonding layer 21b based on transparent conductive oxide is formed at the electron injection regions 201.

As illustrated in FIG. 7D, the sets 20, 30 of nanowires 200, 300 are next assembled by oxide-oxide bonding between the bonding layers 21a, 21b, for example by molecular bonding. In this embodiment, the manipulation substrate H3 carrying the set 30 of nanowires 300 is turned over so as to put the bonding layers 21a, 21b facing each other. An alignment is required for assembling the layers 21a, 21b, which have reduced lateral dimensions. In this embodiment, the bonding layers 21a, 21b advantageously form both the second top electrical contact layer 21 and the third top electrical contact layer 31. The substrate S1 is next removed.

As illustrated in FIG. 7E, after removal of the manipulation substrate S1, the first top electrical contact layer 11 based on transparent conductive oxide is formed at the electron injection regions 101. One or more vias 120, 210 are typically formed through the first set 10 of nanowires 100 to connect the layer forming the bottom electrical contact layers 12, 22.

As illustrated in FIG. 7F, the manipulation substrate H3 is next removed.

As illustrated in FIG. 7G, after removal of the manipulation substrate H3, the third metal bottom electrical contact layer 32 can be formed at the hole injection regions 303. One or more vias 220, 310 can next be formed through the third bottom electrical contact layer 32 and the set 30 of nanowires 300 so as to electrically connect the layer forming the top electrical contact layers 21, 31.

As illustrated through the preceding examples, the devices and methods according to the invention therefore advantageously make it possible to produce subpixels stacked in a main direction of emission of the light radiation with improved extraction efficacy. This makes it possible to produce pixels with reduced lateral dimensions that can advantageously be integrated in high-resolution screens, for example for augmented reality applications.

However, the invention is however not limited to the previously-described embodiments.

1. An optoelectronic device comprising a plurality of emitting layers in a stack in a direction z, said plurality of emitting layers comprising at least:
A first emitting layer comprising a first active part configured to emit a first radiation at a first wavelength λ1,
A second emitting layer comprising a second active part configured to emit a second radiation at a second wavelength λ2 different from the first wavelength λ1,
said emitting layers being at least partly superimposed in projection along the direction z,
each emitting layer furthermore comprising, on either side of the active part:
a bottom electrical contact layer, and
a top electrical contact layer, said top electrical contact layer being transparent at the emission wavelength λ1, λ2 of the emitting layer in question
wherein each of the emitting layers comprises a set of nanowires oriented longitudinally in the direction z forming the active part of the emitting layer said sets of nanowires being distinct from each other.

2. The device according to claim 1, wherein the nanowires are arranged in one and the same emitting layer to form a photonic crystal.

3. The device according to any claims 1, wherein the active parts of the emitting layers are disposed in a staircase, so that each of the sets of nanowires has at least a part not covered by the other sets of nanowires.

4. The device according to claim 1, wherein, for each emitting layer:
the bottom electrical contact layer is reflective at the emission wavelength λ1, λ2 of the emitting layer in question, and
the top electrical contact layer is transparent at the emission wavelength λ1, λ2 of the emitting layer in question,
and wherein said transparent top electrical contact layers are not surmounted by the sets of nanowires.

5. The device according to claim 1, wherein:
the bottom electrical contact layer located under all the active parts of the device is reflective at the emission wavelength λ1, λ2 of said active parts,
the other bottom electrical contact layers are transparent at the wavelengths λ1, λ2 of the active parts located under said other bottom electrical contact layers, and
the top electrical contact layers are transparent at the emission wavelengths λ1, λ2 of the active parts located under said top electrical contact layers.

6. The device according to claim 1, wherein all the bottom electrical contact layers are connected together.

7. The device according to claim 1, wherein two active parts adjacent in the direction z share the same transparent electrical contact layer.

8. The device according to claim 1, wherein the top electrical contact layer of an emitting layer corresponds to the top electrical contact layer of another emitting layer located immediately above said emitting layer

9. The device according to claim 1, wherein at least some of the bottom and top electrical contact layers are connected by vias passing through at least one set of nanowires in the direction z.

10. The device according to any claim 1, wherein the plurality of emitting layers comprises at least one third emitting layer comprising a third active part configured to emit a third radiation at a third wavelength λ3, with λ1≠λ2≠λ3, said third emitting layer comprising a third set of nanowires oriented longitudinally in the direction z and forming said third active part.

11. An emissive screen comprising a plurality of pixels formed by optoelectronic devices according to claim 1, disposed side by side in a plane transverse to the direction z.

12. A method of manufacturing an optoelectronic device according to claim 1, said method comprising at least the following steps:
Forming on a first substrate a first set of nanowires configured to emit the first radiation at the first wavelength λ1,
Forming a first bonding layer for the first set of nanowires,
Forming on a second substrate a second set of nanowires configured to emit the second radiation at the second wavelength λ2,
Forming a second bonding layer for the second set of nanowires,
Putting the second bonding layer facing the first bonding layer,
Assembling the first and second sets of nanowires by bonding at the first and second bonding layers,
Removing at least one of the first and or second substrates,
Forming a first bottom electrical contact layer and a first top electrical contact layer for the first set of nanowires, and
Forming a second bottom electrical contact layer and a second top electrical contact layer for the second set of nanowires.

13. The method according to claim 12, wherein the first and second bonding layers comprise respectively first and second metal layers, the first and second sets of nanowires being assembled by thermal bonding of said first and second metal layers, said first and second metal layers forming the first bottom electrical contact layer, the method further comprising, after at least one of the first or second substrate is assembled and removed:
an etching of part of the first set of nanowires and of the first and second bonding layers, so as to expose part of the second set of nanowires, and
a deposition of a layer of transparent conductive oxide on the exposed part of the second set of nanowires, to form the second top electrical contact layer.

14. The method according to claim 13, further comprising the deposition of a transparent encapsulation layer on the layer of transparent conductive oxide on the exposed part of the second set of nanowires.

15. The method according to claim 12, wherein the first and second bonding layers comprise respectively first and second transparent dielectric layers, the first and second sets of nanowires being assembled by molecular bonding of said first and second metal layers, said first and second transparent dielectric layers forming an intermediate dielectric layer between the first bottom electrical contact layer and the second top electrical contact layer.

16. The method according to claim 12, wherein the first and second bonding layers comprise respectively first and second transparent conductive layers of oxide, the first and second sets of nanowires being assembled by molecular bonding of said first and second transparent conductive layers of oxide, said first and second transparent conductive layers of oxide forming both the first bottom electrical contact layer and the second bottom electrical contact layer.
